(19) United States
(12) Patent Application Publication
(10) Pub. No.: US 2026/0215204 A1
(43) Pub. Date: Jul. 23, 2026

(54) LASER CLEANING APPARATUS AND LASER CLEANING METHOD THEREOF

(71) Applicant: MainType Opto-Electronics Technology Co., LTD., TAIPEI CITY (TW)

(72) Inventor: HUAN-YANG CHENG, NEW TAIPEI CITY (TW)

(21) Appl. No.: 19/431,996

(22) Filed: Dec. 23, 2025

Related U.S. Application Data
(60) Provisional application No. 63/747,080, filed on Jan. 19, 2025.

(51) Int. Cl. H10P 72/00; B23K 26/40; B23K 26/70; H10P 70/00

(52) U.S. Cl. CPC H10P 72/0428; B23K 26/40; B23K 26/707; H10P 70/54

(57) ABSTRACT

The present disclosure provides a laser cleaning apparatus and a laser cleaning method thereof. The laser cleaning apparatus includes a wafer holding module, a laser source, a coating characteristic detection module, a temperature monitoring module, a cleaning assistance module, and a reflective light guidance element. The coating characteristic detection module detects the thickness and the characteristics of the contaminants on the wafer and the laser source automatically configure the parameters of the laser beam according to the detection result of the coating characteristic detection module so as to optimize the cleaning process for contaminants of different types. The laser cleaning apparatus effectively improves cleaning efficiency and high uniformity, while simultaneously reducing potential thermal damage and warpage during the cleaning process. As a result, it achieves higher reliability and reduces process risks.

### CROSS REFERENCE

This application claims the benefit of prior-filed U.S. provisional application No. 63/747,080, filed on Jan. 19, 2025, which is incorporated by reference in its entirety.

### TECHNICAL FIELD

The present disclosure relates to a laser cleaning apparatus and a method, and more particularly, to a laser cleaning apparatus and a method for removing contaminants on a wafer.

### DISCUSSION OF THE BACKGROUND

In conventional wafer cleaning processes, such as mechanical polishing, irreversible substrate damage is often incurred due to direct physical contact. Alternatively, chemical wet cleaning methods may introduce chemical contamination and impose significant environmental burdens. In response to these limitations, laser cleaning technology has attracted considerable attention in recent years. The primary advantages of laser cleaning include non-contact operation without mechanical wear, preventing the chemical contamination caused by chemical agents.

Laser cleaning operates by irradiating the contaminant layer with laser energy, inducing physical effects such as evaporation, micro-explosions, and ablation, thereby removing contaminants from the wafer surface. At higher energy levels, intense instantaneous gas expansion and pressure effects further enhance the particle removal efficiency. However, prior studies (e.g., M. Mosbacher, SPIE 4426, 2002) have indicated that high-energy laser cleaning is frequently accompanied by thermal expansion and thermal stress effects on the wafer surface, which may result in thermal damage.

Various prior art references have attempted to mitigate such thermal injury. For example, Taiwan Pat No. I746220 discloses a laser module with switchable wavelengths to improve path planning, yet lacks fine modulation of laser energy, rendering thermal effects unavoidable. U.S. Pat. No. 6,635,845 employs a dual-laser architecture to separately address inorganic and organic contaminants, thereby reducing high-temperature damage, while US Pub. No. 2009/0291544 and US Pub. No. 2010/0096371 propose zonal cleaning and optical splitting systems, respectively, to enhance efficiency and uniformity. However, existing technologies generally lack systems capable of dynamically adjusting laser parameters according to the characteristics of the contaminant layer, while simultaneously controlling thermal stress, maintaining cleaning quality, and avoiding wafer warping. Accordingly, there remains room for improvement in this field.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In view of the shortcomings of the prior art, the purpose of the present invention is to provide a laser cleaning apparatus and a method thereof capable of ablating and removing heterogeneous contaminants from the wafer surface and adjust the corresponding cleaning parameters according to the contamination conditions in different regions of the wafer, ensuring that each area receives appropriate and thorough cleaning. The proposed apparatus and method effectively improve cleaning efficiency and high uniformity, while simultaneously reducing potential thermal damage and warpage during the cleaning process.

To achieve the aforementioned goals, the proposed laser cleaning apparatus and method integrate a wafer holding module for holding the wafer, a laser source for modulating parameters of the laser, such as laser power and the wavelength of the laser, a fiber coupling module for guiding the laser, an optical module for converging the laser beam onto the area to be cleaned on the wafer, a coating characteristic detection module for detecting the characteristics, such as the thickness or the material, of the contaminants on the wafer, a temperature monitoring module for monitoring the temperature of the wafer and the heat accumulation condition of the wafer, a cleaning assistance module for removing the particles produced during the cleaning process, and a reflective light guidance element for guiding the laser beam onto an edge of the wafer. By coordinating the different modules of the laser cleaning apparatus, the surface and the edge of the wafer can both be cleaned by the laser beam with high efficiency, high uniformity, and low thermal damage.

One aspect of the present disclosure provides a laser cleaning apparatus for removing contaminants on a surface of a wafer. The laser cleaning apparatus includes a wafer holding module, and a laser source. The wafer holding module holds the wafer. The laser source generates a laser beam to clean the wafer. The laser source includes a laser modulator and a laser head. The laser modulator modulates the laser beam to control parameters of the laser beam according to at least one characteristic of the contaminants. The parameters of the laser beam include at least one of a wavelength, a pulse frequency, a pulse width, and a wave power. The laser head outputs the laser beam.

Another aspect of the present disclosure provides a laser cleaning method for removing contaminants on a surface of a wafer by utilizing the laser cleaning apparatus. The method includes instrument, at least one characteristic of the contaminants on the surface of the wafer; wherein, the characteristics including organic/inorganic layer thickness and organic/inorganic compositions of the contaminants, setting, by the laser modulator, the wave power, the pulse frequency, the pulse width, and the wavelength of a first laser beam according to the layer thickness and compositions of the contaminants on the surface of the wafer, setting, by a laser head control module, an incident angle, a sweeping speed, a sweeping frequency, and a sweeping width of the laser head, and performing, by the laser source, a first sweep upon the wafer along a sweeping path to ablate and remove the contaminants on the surface of the wafer with the first laser beam.

The apparatus and method for wafer treatment provided by the present disclosure are capable of ablating and removing heterogeneous contaminants from the wafer surface and adjust the corresponding cleaning parameters according to the contamination conditions in different regions of the wafer, ensuring that each area receives appropriate and thorough cleaning. The system effectively improves cleaning efficiency and high uniformity, while simultaneously reducing potential thermal damage and warpage during the cleaning process. As a result, it achieves higher reliability and reduces process risks.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a laser cleaning apparatus 100 according to one embodiment of the present disclosure.

FIG. 2 shows a more detailed perspective of the platform and the cooling troughs of the wafer holding module according to one embodiment of the present disclosure.

FIG. 3 shows a more detailed view of the laser source, the coating characteristic detection module and the temperature monitoring module according to one embodiment of the present disclosure.

FIG. 4 shows a utilizing scenario of the laser cleaning apparatus in FIG. 1 according to one embodiment of the present disclosure.

FIGS. 5A and 5B show a flow chart of a laser cleaning method by utilizing the laser cleaning apparatus in FIG. 1 according to one embodiment of the present disclosure.

### DETAILED DESCRIPTION

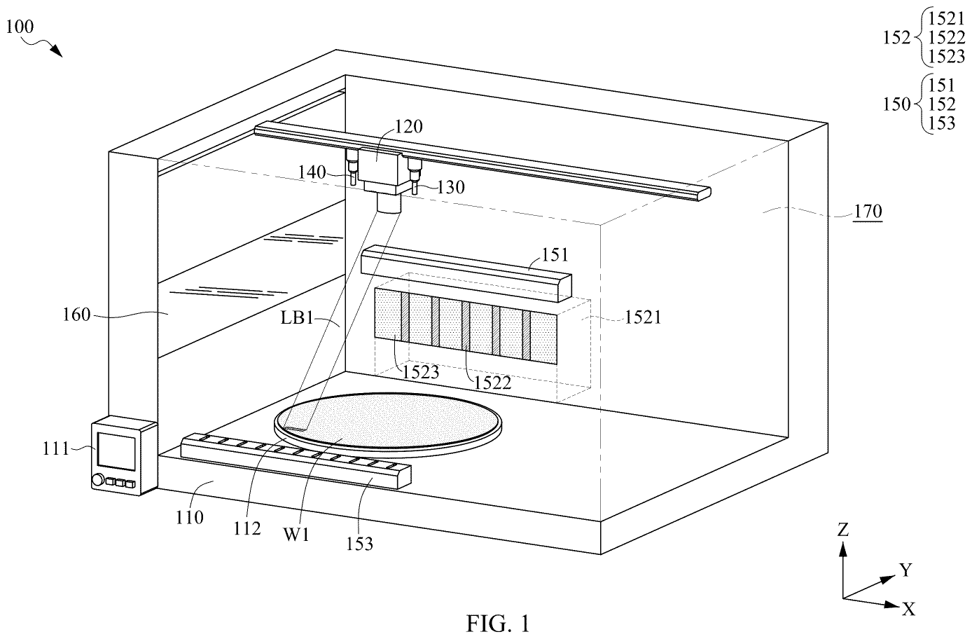

FIG. 1 shows a laser cleaning apparatus 100 for removing contaminants on a wafer W1 according to one embodiment of the present disclosure. The laser cleaning apparatus 100 includes a wafer holding module 110, a laser source 120, a coating characteristic detection module 130, a temperature monitoring module 140, a cleaning assistance module 150, a reflective light guidance element 160, and a chamber 170. In some embodiments, the wafer W1 to be cleaned by the laser cleaning apparatus 100 includes silicon material. For example, the wafer W1 can be silicon wafer, silicon-germanium wafer, silicon-carbide (SiC) wafer, silicon on sapphire (SOS) wafer, silicon on insulator (SoI) wafer, or the like.

In some embodiments, the wafer holding module 110 includes a platform 112 and a position adjustment device 111. The wafer holding module 110 can secure the wafer W1 on the platform 112, and the position adjustment device 111 can move the wafer W1 to the desired position for detection or cleaning according to the needs. In some embodiments, the wafer holding module 110 may adopt the vacuum chucking, electrostatic chucking (ESC), or mechanical clamping (not shown in FIG. 1 for brevity) to hold the wafer W1 on the platform 112. The position adjustment device 111 allows to rotate, move, and/or tilt the wafer W1 so as to facilitate the laser cleaning process or the detection process before cleaning. In some embodiments, the position adjustment device 111 can move the wafer W1 along the X-axis, the Y-axis, and/or the Z-axis. However, the present disclosure is not limited thereto. In some embodiments, the position adjustment device 111 may only allow one or two moving directions.

In FIG. 1, the position adjustment device 111 is illustrated schematically as a control panel that enables a user to manually control the movement of the wafer W1. It should be noted that, for the sake of clarity and conciseness, the mechanical components of the position adjustment device 111—such as motors, rails, tracks, and other elements necessary to effectuate the movement of the wafer W1—are not depicted in the figure. However, it is to be understood that such mechanical components are encompassed within the scope of the present disclosure and may be implemented in various configurations as required to achieve the desired wafer positioning functionality.

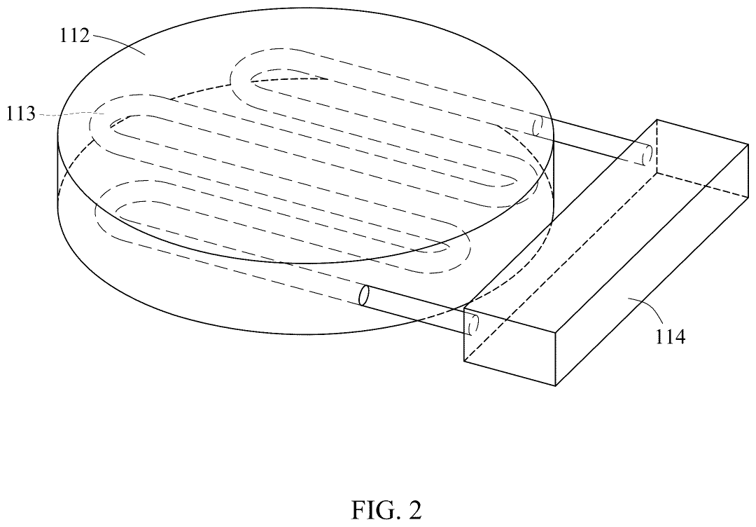

Furthermore, in some embodiments, the platform 112 can have high thermal conductivity so as to reduce the heat accumulation during the laser cleaning process. In some embodiments, to further facilitate the heat dissipation, the wafer holding module 110 may also include cooling troughs within the platform 112. FIG. 2 shows a more detailed perspective of the platform 112 and the cooling troughs 113 of the wafer holding module 110 according to one embodiment of the present disclosure. As shown in FIG. 2, the wafer holding module 110 may further include a cooling medium control module 114. The cooling medium control module 114 may control the flowing speed of the cooling medium (such as cooling inert gas, for example nitrogen, carbon dioxide, argon or cooling liquid) that flows through the cooling troughs 113.

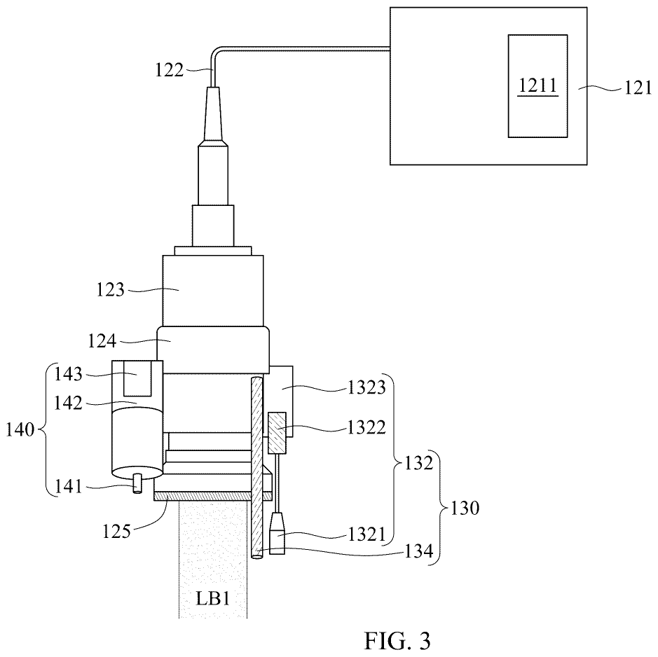

The laser source 120 is employed to generate a laser beam LB1 for cleaning the wafer W1. FIG. 3 shows a more detailed view of laser source 120 according to one embodiment of the present disclosure. As shown in FIG. 3, the laser source 120 may include a laser modulator 121, a fiber coupling module 122, a laser head 123, a laser head control module 124, and a laser focus lens 125. The laser modulator 121 can modulate the laser beam to control parameters of the laser beam LB1. For example, the laser modulator 121 may include a wavelength converting module 1211 for adjusting the wavelength of the laser beam LB1. In some embodiments, although not explicitly illustrated in FIG. 1 or FIG. 3 for the sake of conciseness, the laser modulator 121 may additionally include one or more modules configured to control various parameters of the laser. These parameters may include, but are not limited to, pulse frequency, pulse width, output power, and waveform shape.

The fiber coupling module 122 can couple the modulated laser beam to the laser head 123 through the fiber, so that the laser head 123 can output the coupled laser beam. Furthermore, the laser head control module 124 is coupled to the laser head 123 and can control an incident angle, a sweeping speed, a sweeping width, a sweeping frequency and a sweeping region of the laser head 123. In some embodiments, the laser head control module 124 is further interconnected to the position adjustment device 111 so that when the position adjustment device 111 moves or tilts the wafer W1, the laser beam LB1 can still be emitted with the desired incident angle and aiming to the targeted position. As the laser beam is outputted by the laser head 123, the laser focus lens 125 is employed to converge laser beam LB1 onto the surface of the wafer W1 so as to ablate and remove the contaminants on the surface of the wafer W1 with higher power.

The coating characteristic detection module 130 is employed to analyze at least one characteristic of the contaminants on the surface of the wafer W1 to be removed. FIG. 3 further shows a more detailed view of the coating characteristic detection module 130. For example, the coating characteristic detection module 130 may include a spectral detection module 132 for detecting the thickness and the optical properties of the contaminants on the wafer W1, and a material analysis module 134 for detecting the material of the contaminants on the wafer W1.

Specifically, the spectral detection module 132 is adopted to measure the reflected spectrum from the surface of the wafer W1 to obtain the thickness and optical parameters of the contaminants (i.e., the coating) on the surface of the wafer W1. In some embodiments, the spectral detection module 132 may include a fiber sensor probe 1321, a spectral acquisition unit 1322, and an optical analyzer 1323.

In some embodiments, the fiber sensor probe 1321 is positioned in proximity to the laser head 123 to ensure that its measurement optical path is accurately directed toward the wafer W1. In such case, to measure the characteristics of the contaminants on the wafer W1, the fiber sensor probe 1321 collects the light reflected from the surface of the wafer W1, and the reflected light is transmitted to the spectral acquisition unit 1322, thereby allowing the optical analyzer 1323 to analyze the thickness and the optical properties of the coating on the wafer W1. In the present embodiment, the measuring result is feedback to the laser modulator 121 or the laser head control module 124 so that the laser source 120 can adjust the parameters of the laser beam used for cleaning the wafer W1.

The material analysis module 134 may include a Raman probe or a laser-induced plasma spectroscopy (LIPS) device for analyze the composition of the contaminants on the wafer W1. In some embodiments, the material analysis module 134 is able to analyze the types of contaminant materials, the presence of residual oxides, organic residues, and/or metal contamination.

Since different types of contaminants may have different laser absorption spectrum characteristic, the laser modulator 121 is able to control parameters of the laser beam LB1 according to the characteristic of the contaminants obtained by the coating characteristic detection module 130. In other words, the laser modulator 121 may adjust the parameters of the laser beam LB1 according to the thickness, the optical properties, and/or the types of the contaminants so as to clean the wafer W1 with better efficiency and lower damage.

In the present embodiment, the coating characteristic detection module 130 includes both the spectral detection module 132 and the material analysis module 134. However, the present disclosure is not limited thereto. In some embodiments, the coating characteristic detection module 130 may omit one of the spectral detection module 132 or the material analysis module 134 according to the practical needs. Furthermore, in some embodiments, the laser cleaning apparatus 100 may omit the coating characteristic detection module 130, and the characteristic of the contaminants on the surface of the wafer W1 can be instrumented by other detecting apparatus that is independent of the laser cleaning apparatus 100. In such case, the laser source 120 may receive the characteristic of the contaminants from the external detecting apparatus.

The temperature monitoring module 140 is employed to monitor the heat distribution on the surface of the wafer W1 so as to protect the wafer W1 from overheated. FIG. 3 further shows a more detailed view of the coating characteristic detection module 130. As shown in FIG. 3, the temperature monitoring module 140 may include a thermal sensor 141, a thermal analyzer 142, and a feedback controller 143. The thermal sensor 141 is directed toward the wafer W1 or the platform 112 so as to measure the temperature of the wafer W1. The temperature information is then transmitted to the thermal analyzer 142 to analyze the heat distribution of the wafer W1. The analyzing result of the thermal analyzer 142 is transmitted to the feedback controller 143, and the feedback controller 143 can be interconnected to the wafer holding module 110 so as to allow the position adjustment device 111 to adjust the position of the wafer W1 and allow the cooling troughs within the wafer holding module 110 to adjust the cooling intensity according to the thermal information derived by the thermal analyzer 142. In addition, in some embodiments, the feedback controller 143 can be interconnected to the laser source 120 so as to allow the laser modulator 121 to adjust the parameters of the laser beam LB1 (such as the laser power) and allow the laser head control module 124 to adjust the sweeping speed according to the thermal information derived by the thermal analyzer 142, thereby keeping the heat accumulation of the wafer W1 within a safe range.

The cleaning assistance module 150 can collect particle dusts caused by ablation and removal of the contaminants on the surface of the wafer W1. In some embodiments, the laser cleaning process is performed within the chamber 170 so that the cleaning assistance module can have better control of the environment condition. Also, the chamber 170 can prevent the foreign dust from attaching to the wafer W1 and prevent the contaminants removed by the laser from polluting the environment outside the chamber.

In some embodiments, the cleaning assistance module 150 includes a jet spray nozzle 151, a high-efficiency particulate air (HEPA) system 152, and an exhaust module 153. The jet spray nozzle 151 is disposed above the laser sweeping region. The jet spray nozzle 151 is able to generate a sheet of gas flow that blows onto the surface of the wafer W1, thereby cooling the wafer W1 swept by the laser beam LB1 and remove particles produced by the ablation of the laser cleaning process. In some embodiments, the gas outputted by the jet spray nozzle 151 may include Argon, Nitrogen, Carbon dioxide, or the like.

The HEPA system 152 is disposed at an upstream position from the stage 112 of the laser cleaning apparatus 100. The HEPA system 152 may include a ducting blower 1521, a flow straightener 1522, and a HEPA filter 1523. The ducting blower 1521 pumps the gas through the flow straightener 1522 and the HEPA filter 1523 to form a clean laminar air flow, so as to maintain a low particle environment for the laser cleaning apparatus 100 and prevent the particles or dust from resettling on the surface of the wafer W1. The exhaust module 153 is disposed at a downstream position of the laser cleaning apparatus 100 so as to extract smoke and particles generated during the cleaning process. As a result, the jet spray nozzle 151, the HEPA system 152 and the exhaust module 153 form a complete airflow path and enhances the efficiency of pollutant removal.

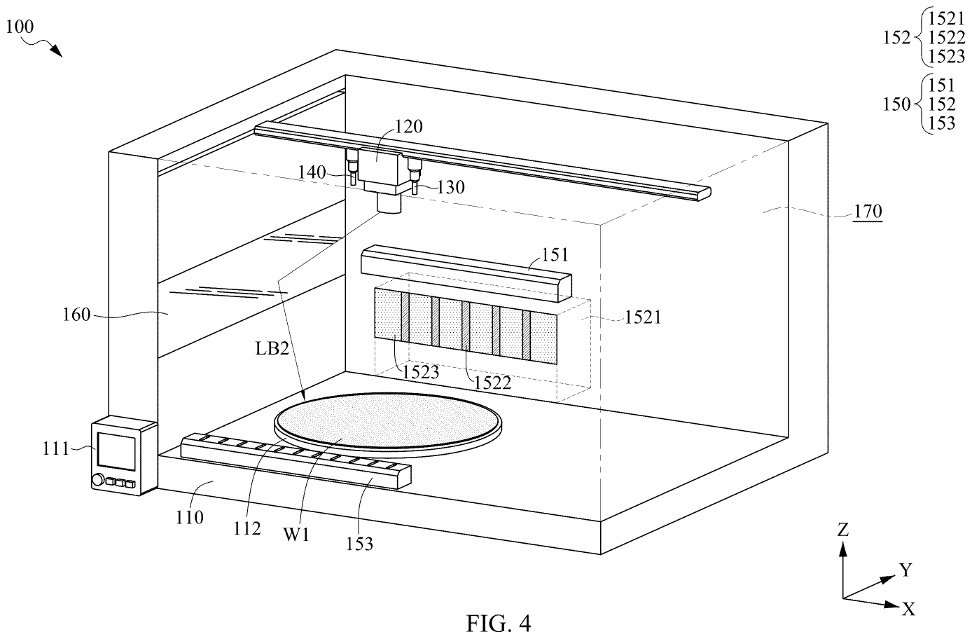

The reflective light guidance element 160 is employed to guide the laser beam outputted by the laser head 123 onto an edge of the wafer W1, thereby allowing the laser cleaning apparatus 100 to clean both the surface and the edge of the wafer W1. The reflective light guidance element 160 can be disposed at the boundary of the laser sweeping region or near the edge of the wafer W1. FIG. 4 shows a utilizing scenario of the laser cleaning apparatus 100 according to one embodiment of the present disclosure. As shown in FIG. 4, the reflective light guidance element 160 allows it to redirect the laser beam LB2 outputted by the laser head 123, through reflection and/or refraction, onto the edge of the wafer W1. By redirecting the laser beam LB2, the edge areas that were difficult to be irradiated by the laser can also receive sufficient laser energy so as to be cleaned by the laser.

By coordinating the wafer holding module 110, the laser source 120, the coating characteristic detection module 130, the temperature monitoring module 140, the cleaning assistance module 150, and the reflective light guidance element 160, the laser cleaning apparatus 100 is able to clean the wafer W1 with high stability, high controllability, high process consistency, low damage, and low pollution.

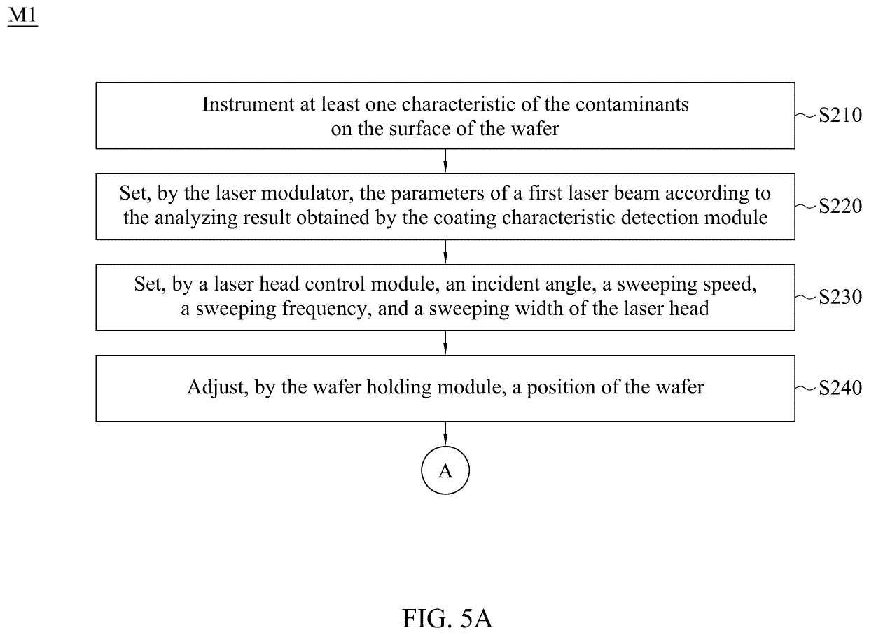

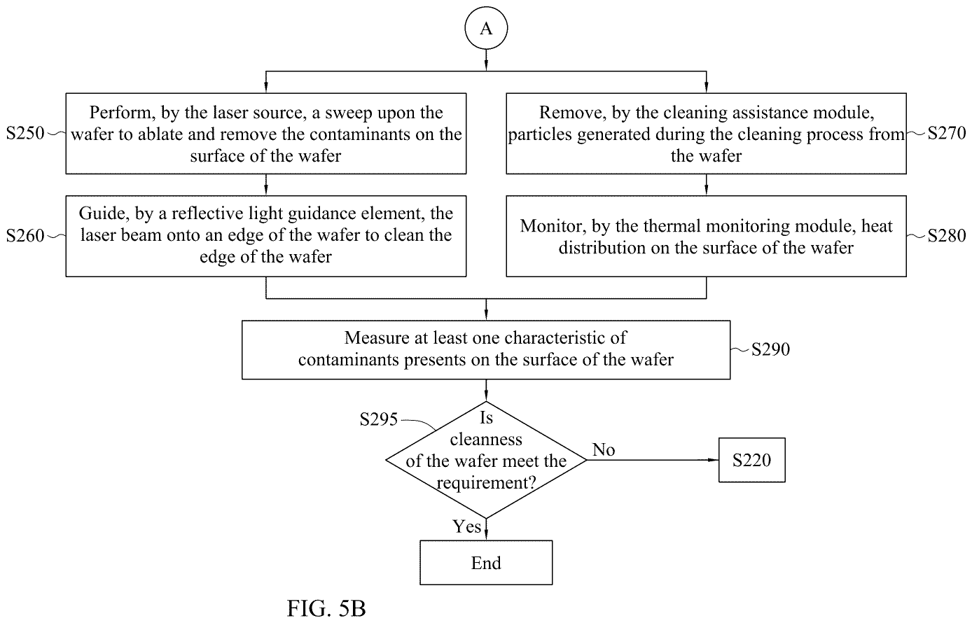

FIGS. 5A and 5B show a flow chart of a laser cleaning method M1 by utilizing the laser cleaning apparatus 100. As shown in FIGS. 5A and 5B, the method M1 includes steps S210 to S295. It should be understood that the method M1 disclosed herein is not limited to the sequence of steps depicted in FIGS. 5A and 5B. In various embodiments, certain steps may be performed concurrently or may be executed in a sequence different from that illustrated, without departing from the scope of the present disclosure.

In step S210, the wafer W1 is under detection for measuring at least one characteristic of the contaminants on the wafer W1. In some embodiments, the laser cleaning apparatus 100 may include the coating characteristic detection module 130 for executing step S210. However, in some embodiments, the laser cleaning apparatus 100 may omit the coating characteristic detection module 130. In such case, step S210 may be executed by another detecting apparatus independent of the laser cleaning apparatus 100.

With the measuring result obtained in step S210, the parameters of the laser beam LB1 can be set accordingly by the laser modulator 121 in step S220. In some embodiments, the configurable parameters of the laser beam LB1 that can be set by the laser modulator 121 may include the wave power, the pulse frequency, the pulse width, and the wavelength. In some embodiments, if the contaminant exhibits superior absorbance for light at a specific wavelength, then the laser modulator 121 may modulate the laser beam LB1 to have such wavelength so as to remove the contaminants with better efficiency. For example, the organic material may have better absorbance for lights with wavelength at 335 nm, and the metal material may have better absorbance for lights with wavelength at 532 nm or 1064 nm. Therefore, if the contaminants on the wafer W1 includes organic material, the laser modulator 121 may modulate the laser beam LB1 to have a wavelength of 355 nm. Alternatively, if the contaminants on the wafer W1 includes metals, the laser modulator 121 may modulate the laser beam LB1 to have a wavelength of 532 nm or 1064 nm.

In addition, generally, the laser modulator 121 may modulate the laser beam LB1 to have a wave power within a range from 100 W to 2000 W, a pulse frequency within a range from 24 kHz to 3000 kHz, and a pulse width within a range from 2 ns to 200 ns. By setting the parameters of the laser beam LB1 specifically according to the characteristics of the contaminants in step S220, the laser cleaning apparatus 100 is able to clean the contaminants with optimal laser beam LB1, thereby concentrating the laser energy on the contaminants rather than the substrate of the wafer W1. As a result, the cleaning efficiency can be improved, and the heat accumulation on the wafer W1 can be reduced.

In step S230, the laser head control module 124 can further set the incident angle, the sweeping speed, the sweeping frequency, and the sweeping width of the laser head 123, so the laser source 120 can sweep the wafer W1 along a sweeping path to clean the wafer with the optimized configuration. After the laser source 120 is ready for sweeping the wafer W1 and before the sweeping starts, the wafer holding module 110 may adjust the position and/or the tilt angle of the wafer W1 according to the configuration of the laser source 120 in step S240. For example, the wafer W1 may be adjusted to a position such that the laser beam outputted by the laser source 120 can be converged on the desired spot of the wafer W1. Consequently, the laser source 120 is allowed to ablate and remove the contaminants on the surface of the wafer W1 in step S250 with the desired setting and under the optimal optical path conditions. In some embodiments, the sweeping path can be, for example but not limited to, a linear path, a zig-zag path or a spiral path.

In some embodiments, the laser head control module 124 can control the incident angle of the laser beam relative to the surface of the wafer W1 within a range from −25° to 25°. In some embodiments, the laser head control module 124 may control the laser beam LB1 to sweep along the X-axis and the Y-axis on the surface of the wafer W1, thereby forming a two-dimensional scanning trajectory. Furthermore, the laser head control module 124 can control an overlap rate between consecutive X-axis and Y-axis sweeps within a range from 1% to 100% so as to ensure that a cleaning energy is uniformly distributed across all regions of the surface of the wafer W1. In some embodiments, the laser head control module 124 can control the sweeping width within a range from 1 mm to 400 mm, and control the effective sweeping area of the laser beam within a range from 1 mm×1 mm to 400 mm×400 mm.

In some embodiments, for 100 mm² chips on 12 inches silicon wafer and the characteristic of the contaminants are metallic, particulate as well as organic molecular contaminations and 2.2 μm in thickness after instrumenting. At first cleaning level, the level induces micro-explosion and evaporation to the contaminants on the surface of the wafer, the laser head control module 124 modulates the maximum power withstand under the feature of the wafer as well as the 15~20 KHz pulse frequency of laser beam LB1. The incident angle is selected to be 45°, the sweeping speed is 40 min/mm and the sweeping frequency is 50 Hz, and the sweeping width is 60 mm by the laser head control module 124.

At a second cleaning level, the level functions smoothing the surface of the wafer, the laser head control module 124 modulates the 70% power withstand under the feature of the wafer as well as the 20~30 KHz pulse frequency of laser beam LB1. The incident angle is selected to be 45°, the sweeping speed is 60 min/mm and the sweeping frequency is 20 Hz, and the sweeping width is 100 mm by the laser head control module 124.

At a third cleaning level, the level reduces the thermal stress of the wafer, the laser head control module 124 modulates the 50% power withstand under the feature of the wafer as well as the 30~40 KHz pulse frequency of laser beam LB1. The incident angle is selected to be 30°, the sweeping speed is 2.5 min/mm and the sweeping frequency is 5 Hz, and the sweeping width is 200 mm by the laser head control module 124.

In some embodiments, for 100 mm² chips on 6 inches SiC wafer, the composition and thickness of the contaminant layer were determined after instrumental analysis. At the first cleaning level, the level induces micro-explosion and evaporation to the contaminants on the surface of the wafer, the laser head control module 124 modulates the 300W power and the 10~15 KHz pulse frequency of laser beam LB1. The incident angle is selected to be 60°, the sweeping speed is 30 min/mm and the sweeping frequency is 30 Hz, and the sweeping width is 30 mm by the laser head control module 124. At the second cleaning level, the level functions smoothing the surface of the wafer, the laser head control module 124 modulates 200 W power and 20~30 KHz pulse frequency of laser beam LB1. The incident angle is selected to be 60°, the sweeping speed is 40 min/mm and the sweeping frequency is 10 Hz, and the sweeping width is 100 mm by the laser head control module 124. At the third cleaning level, the level reduces the thermal stress of the wafer, the laser head control module 124 modulates the 100 W power and 30~40 KHz pulse frequency of laser beam LB1. The incident angle is selected to be 45°, the sweeping speed is 5 min/mm and the sweeping frequency is 5 Hz, and the sweeping width is 200 mm by the laser head control module 124.

In some embodiments, the wafer W1 may be divided into multiple different regions, and the contaminant characteristics for the different regions on the wafer W1 can be detected individually. Since the contaminants may have different characteristics in the different regions of the wafer W1, the laser modulator 121 and the laser head control module 124 may be reconfigured before cleaning each region so as to ensure that each region on the wafer W1 can be cleaned by the laser beam with the optimized setting and optical path according to the characteristics of the contaminants in such region. In some embodiments, the measurement of the contaminants in all regions of the wafer W1 can be performed at once in step S210, and the laser modulator 121 and the laser head control module 124 may be reconfigured in steps S220 and S230 each time before step S250 is performed to clean a corresponding region. In such case, steps S210, S220, S230, S240, and S250 may be performed repeatedly for cleaning all the different regions on the wafer W1. However, the present disclosure is not limited thereto. In some embodiments, if the contaminants on the wafer W1 is uniformly distributed, then step S210 may only be performed to one or parts of the regions on the wafer W1 as a reference. In such case, steps S220, S230, and S240 may be performed once, and step S250 may be performed with the same configuration set in steps S220 and S230 for all the regions on the wafer W1.

In addition to cleaning the surface of the wafer in step S250, step S260 can also be performed to clean the edge of the wafer W1. In step S260, the laser beam LB2 is guided onto the edge of the wafer W1 to clean the edge of the wafer by the reflective light guidance element 160. In some embodiments, with the aid of the reflective light guidance element 160, residual adhesive or metal oxide contamination in areas that are difficult to irradiate directly, such as edge chamfers or outer peripheries, can also be cleaned.

In some embodiments, steps S270 and S280 may be executed with steps S250 and S260 concurrently. In step S270, the cleaning assistance module 150 can remove particles generated during the cleaning process of steps S250 and S260 from the wafer W1 to prevent particle redeposition and to keep the optical paths of the laser beams LB1 and LB2 clean. Specifically, the jet spray nozzle 151 may generate a sheet of gas flow that blows onto the surface of the wafer W1, thereby removing the particles produced by the ablation of the laser cleaning process and cooling the wafer W1 swept by the laser beam and. Also, the HEPA system 152 may form a clean laminar air flow from up to down so as to maintain a low particle environment for the laser cleaning apparatus 100. The exhaust module 153 may further extract the smoke and the particles to keep the chamber of the laser cleaning apparatus 100 clean.

In step S280, the temperature monitoring module 140 monitors the heat distribution on the surface of the wafer W1 so as to protect the wafer W1 from overheated. Specifically, in step S280, the thermal sensor 141 measures the temperature of the wafer W1 and the platform 112 continuously, and the temperature information is then transmitted to the thermal analyzer 142 to analyze the heat distribution of the wafer W1 to check if there is a local area or overall excessive temperature. Accordingly, the feedback controller 143 of the temperature monitoring module can regulate the cooling intensity, the power of the laser beam, and/or the sweeping speed based on the analysis results provided by the thermal analyzer 142, thereby maintaining the heat accumulation on the wafer W1 within a safe range. This prevents the wafer W1 from warping due to thermal expansion and contraction.

After the cleaning process performed in steps S 250 and S260, the coating characteristic detection module 130 can be activated again in step S290 so as to measure at least one characteristic presents on the contaminants on the surface of the wafer W1 again, so as to determine if another cleaning process is needed or not.

For example, the spectral detection module 132 may detect the thickness and the optical properties of the contaminants on the wafer W1 again, and the material analysis module 134 may detect the material of the contaminants on the wafer W1 again. However, in some embodiments, if the laser cleaning apparatus 100 omits the coating characteristic detection module 130, then step S290 may be executed by another detecting apparatus independent of the laser cleaning apparatus 100. The measuring result of step S290 can be compared with the result of the first analysis performed in step S210 so as check if the cleaning process is effective. Also, the result of the second analysis may be compared to a predetermined constrain, which may define an acceptable threshold or proportion of a specific material present within the contaminants, or may specify other relevant criteria. In such case, if the contaminants left on the wafer W1 do not meet the requirements, then steps S220 to S290 may be performed again to further clean the remaining contaminants. It should be noticed that, since the characteristics of the contaminants may be altered after the first cleaning process (e.g., the contaminants may become thinner, or some materials may appear after the first cleaning process), the laser source 120 may be reconfigured according to the result of the second analysis before performing the second sweep to clean the wafer W1. In such case, the laser beam used in the second sweep may have a parameter setting different from that of the laser beam used in the first sweep. For example, the power and/or the wavelength of the laser beam used in the second sweep may be different from the power and/or the wavelength of the laser beam used in the first sweep.

In some embodiments, multiple sweeps may be performed upon the wafer W1 until the wafer W1 is determined to be cleaned to an acceptable degree in step S295. Finally, if the wafer W1 is determined to be clean enough in step S295, the cleaning process can be ended, and a cleaning report may be generated to document the change of the surface of the wafer W1, and the parameters used during the cleaning process.

Furthermore, in some embodiments, during the cleaning process, the laser beam may cause melting, vaporizing and/or micro-explosion on the wafer W1, which may cause the surface of the wafer W1 uneven. In such case, to improve the flatness of the surface of the wafer W1, an additional laser treatment can be performed upon the surface of the wafer W1 after the cleaning process(es). In some embodiments, the power of the laser beam used in the cleaning process can be lower than the power of the laser beam used in the additional laser treatment. In such case, while the laser cleaning process (e.g., step S250) is focus on ablating and removing the contaminants on the surface of the wafer W1, the additional laser treatment may cause melting, annealing and/or recrystallization upon the surface of the wafer W1 so as to release the thermal stress and make the surface of the wafer W1 more even. In some embodiments, by sweeping the wafer W1 in the additional laser treatment with the laser beam having higher power, the molecules at the surface of the wafer W1 can be rearranged to release the thermal stress, and the recrystallization can reduce surface defects and roughness. As a result, the surface of the wafer W1 can have better uniformity, thereby facilitating the subsequent processes, such as polishing and the washing, for recycle or reuse without requiring the grinding process which is necessary for the conventional wafer cleaning process.

By coordinating the wafer holding module 110, the laser source 120, the coating characteristic detection module 130, the temperature monitoring module 140, the cleaning assistance module 150, and the reflective light guidance element 160, the laser cleaning apparatus 100 and the method M1 allows the user to clean the wafer W1 with high stability, controllability, and process consistency, making it suitable to be integrated into the automated production lines.

Furthermore, since the laser source 120 is able to automatically configure the laser parameters (e.g., the laser wavelength, the pulse frequency, the pulse width, the wave power, the laser incident angle, the sweeping speed, the sweeping width, the sweeping frequency and the sweeping region) based on the thickness, the optical properties, and the types of the contaminants detected by the coating characteristic detection module 130, the cleaning process can be controlled with a closed-loop and can be optimized for contaminants of different types, thereby improving the cleaning efficiency and enhancing the consistency of the cleaning process. Also, the reflective light guidance element 160 allows the cleaning process to further cover the edges of the wafers, which further improves the cleaning uniformity across the entire wafer.

In addition, the temperature monitoring module 140 can monitor the heat accumulation of the wafer W1 and control the heat dissipation accordingly, thereby protecting the wafer from thermal warpage. The cleaning assistance module 150 can provide both airflows and exhaust paths, which enables the immediate removal of particulates and fumes generated during the cleaning process, so that the risk of secondary contamination can be minimized.

In summary, the apparatus and method for wafer treatment provided by the present disclosure are capable of ablating and removing heterogeneous contaminants from the wafer surface and adjust the corresponding cleaning parameters according to the characteristics of the contaminations in different regions of the wafer, ensuring that each area receives appropriate and thorough cleaning. The system effectively improves cleaning efficiency and high uniformity, while simultaneously reducing potential thermal damage and warpage during the cleaning process. As a result, it achieves higher reliability and reduces process risks.

What is claimed is:

1. A laser cleaning apparatus for removing contaminants on a surface of a wafer, the laser cleaning apparatus comprising:
a wafer holding module configured to hold the wafer;
a laser source configured to generate a laser beam to clean the wafer, wherein the laser source comprises:
a laser modulator configured to receive at least one characteristic of the contaminants, and modulate the laser beam to control parameters of the laser beam according to the at least one characteristic of the contaminants, wherein the parameters of the laser beam comprise at least one of a wavelength, a pulse frequency, a pulse width, and a wave power; and
a laser head configured to output the laser beam.

2. The laser cleaning apparatus of claim 1, wherein the laser modulator modulates the laser beam to have a wave power within a range from 100 W to 2000 W, a pulse frequency within a range from 24 kHz to 3000 kHz, a pulse width within a range from 2 ns to 200 ns, and a wavelength of 355 nm, 532 nm or 1064 nm.

3. The laser cleaning apparatus of claim 1, further comprising a reflective light guidance element configured to guide the laser beam onto an edge of the wafer to clean the edge of the wafer.

4. The laser cleaning apparatus of claim 1, wherein the laser source further comprises a laser focus lens configured to converge the laser beam outputted by the laser head onto the surface of the wafer to ablate and remove the contaminants on the surface of the wafer.

5. The laser cleaning apparatus of claim 1, wherein the laser source further comprises a laser head control module configured to control an incident angle, a sweeping speed, a sweeping width, a sweeping frequency and a sweeping region of the laser head.

6. The laser cleaning apparatus of claim 5, wherein the laser head control module is configured to:
control the incident angle of the laser beam relative to the surface of the wafer within a range from −25° to 25°;
control the laser beam to sweep along an X-axis and a Y-axis on the surface of the wafer, thereby forming a two-dimensional scanning trajectory;
control the sweeping width within a range from 1 mm to 400 mm;
control an overlap rate between consecutive X-axis and Y-axis sweeps within a range from 1% to 100% so as to ensure that a cleaning energy is uniformly distributed across all regions of the surface of the wafer; and
control an effective sweeping area of the laser beam within a range from 1 mm×1 mm to 400 mm×400 mm.

7. The laser cleaning apparatus of claim 1, wherein the wafer holding module comprises a platform and a cooling trough configured to allow cooling inert gas or cooling liquid to flow through for heat dissipation.

8. The laser cleaning apparatus of claim 1, wherein the wafer holding module comprises a position adjustment device configured to move the wafer along an X-axis, a Y-axis, and a Z-axis and adjust a tilt angle of the wafer.

9. The laser cleaning apparatus of claim 1, further comprising a cleaning assistance module configured to collect particle dusts caused by ablation and removal of the contaminants on the surface of the wafer, the cleaning assistance module comprises a high-efficiency particulate air (HEPA) system, and an exhaust module, wherein the HEPA system comprises a ducting blower, an flow straightener, and a HEPA filter, wherein the ducting blower is configured to pump gas through the HEPA filter and the flow straightener to form a clean laminar flow, and the exhaust module is configured to extract waste gas generated during cleaning the wafer.

10. The laser cleaning apparatus of claim 9, wherein the cleaning assistance module further comprises a jet spray nozzle configured to produce a sheet of gas flow, and gas outputted by the jet spray nozzle comprises at least one of Argon, Nitrogen, or Carbon dioxide.

11. The laser cleaning apparatus of claim 1, further comprising a coating characteristic detection module configured to measure the at least one characteristic of the contaminants on the surface of the wafer.

12. A laser cleaning method for removing contaminants on a surface of a wafer by utilizing the laser cleaning apparatus of claim 1, the method comprising:
instrumenting at least one characteristic of the contaminants on the surface of the wafer, wherein, the characteristics comprises layer thickness and compositions of the contaminants;
adjusting, by the wafer holding module, a holding position of the wafer;
setting, by the laser modulator, the wave power, the pulse frequency, the pulse width, and the wavelength of a first laser beam according to the at least one characteristic of the contaminants on the surface of the wafer;
setting, by a laser head control module, an incident angle, a sweeping speed, a sweeping frequency, and a sweeping width of the laser head according to the at least one characteristic of the contaminants on the surface of the wafer; and
performing, by the laser source, a first sweep upon the wafer along a sweeping path to ablate and remove the contaminants on the surface of the wafer with the first laser beam.

13. The method of claim 12, wherein the step of setting, by the laser modulator, the wave power, the pulse frequency, the pulse width, and the wavelength of the first laser beam according to the at least one characteristic of the contaminants on the surface of the wafer comprises modulating the first laser beam to have a wave power within a range from 100 W to 2000 W, a pulse frequency within a range from 24 kHz to 3000 kHz, a pulse width within a range from 2 ns to 200 ns, and a wavelength of 355 nm, 532 nm or 1064 nm.

14. The method of claim 12, wherein the step of setting, by the laser head control module, the incident angle, the sweeping speed, the sweeping frequency, and the sweeping width of the laser head comprises:
controlling the incident angle of the first laser beam relative to the surface of the wafer within a range from −25° to 25°;
controlling the first laser beam to sweep along an X-axis and a Y-axis on the surface of the wafer, thereby forming a two-dimensional scanning trajectory;
controlling the sweeping width within a range from 1 mm to 400 mm;
controlling an overlap rate between consecutive X-axis and Y-axis sweeps within a range from 1% to 100% so as to ensure that a cleaning energy is uniformly distributed across all regions of the surface of the wafer; and
controlling an effective sweeping area of the first laser beam within a range from 1 mm×1 mm to 400 mm×400 mm.

15. The method of claim 12, wherein the sweeping path comprises a linear path, a zig-zag path or a spiral path.

16. The method of claim 12, further comprising:
guiding, by a reflective light guidance element, the first laser beam onto an edge of the wafer to clean the edge of the wafer.

17. The method of claim 12, wherein the laser cleaning apparatus further comprising a temperature monitoring module, and the method further comprises:
monitoring, by the temperature monitoring module, heat distribution on the surface of the wafer so as to protect the wafer from overheated.

18. The method of claim 12, further comprising:
after the first sweep, measuring at least one characteristic of contaminants presents on the surface of the wafer again to determine a cleaning degree of the wafer.

19. The method of claim 18, further comprising:
performing a second sweep upon the wafer to ablate and remove the contaminants on the surface of the wafer with a second laser beam, wherein the second laser beam has a parameter setting different from that of the first laser beam.
